(19) United States
(12) Patent Application Publication
(10) Pub. No.: US 2012/0160314 A1
(43) Pub. Date: Jun. 28, 2012

(54) PROCESS FOR THE FORMATION OF A SILVER BACK ANODE OF A SILICON SOLAR CELL

(75) Inventors: Alistair Graeme Prince, Bedminster (GB); Ben Whittle, Bristol (GB)

(73) Assignee: E. I. DU PONT DE NEMOURS AND COMPANY, Wilmington, DE (US)

(21) Appl. No.: 13/168,049

(22) Filed: Jun. 24, 2011

Related U.S. Application Data
(60) Provisional application No. 61/358,143, filed on Jun. 24, 2010.

(51) Int. Cl. H01L 31/0224; H01L 31/18

(52) U.S. Cl. 136/256; 438/98; 257/E31.124

(57) ABSTRACT

A process for the formation of a silver back anode of a silicon solar cell wherein a silver paste comprising particulate silver, an organic vehicle and glass frit comprising at least one antimony oxide is applied in a silver back anode pattern on the back-side of a p-type silicon wafer having an aluminum back-side metallization and fired.

### FIELD OF THE INVENTION

The present invention is directed to a process for the formation of a silver back anode of a silicon solar cell and to the silver back anode produced by the process. Accordingly, it relates also to a process for the production of a silicon solar cell comprising the silver back anode and to the silicon solar cell itself.

### TECHNICAL BACKGROUND OF THE INVENTION

A conventional solar cell structure with a p-type base has a negative electrode that is typically on the front-side or sun side of the cell and a positive electrode on the back-side. It is well known that radiation of an appropriate wavelength falling on a p-n junction of a semiconductor body serves as a source of external energy to generate electron-hole pairs in that body. The potential difference that exists at a p-n junction, causes holes and electrons to move across the junction in opposite directions, thereby giving rise to flow of an electric current that is capable of delivering power to an external circuit. Most solar cells are in the form of a silicon wafer that has been metallized, i.e., provided with metal contacts which are electrically conductive.

Most electric power-generating solar cells currently used are silicon solar cells. Electrodes in particular are made by using a method such as screen printing from metal pastes.

The production of a silicon solar cell typically starts with a p-type silicon substrate in the form of a silicon wafer on which an n-type diffusion layer of the reverse conductivity type is formed by the thermal diffusion of phosphorus (P) or the like. Phosphorus oxychloride (POCl₃) is commonly used as the gaseous phosphorus diffusion source, other liquid sources are phosphoric acid and the like. In the absence of any particular modification, the diffusion layer is formed over the entire surface of the silicon substrate. The p-n junction is formed where the concentration of the p-type dopant equals the concentration of the n-type dopant; conventional cells that have the p-n junction close to the sun side, have a junction depth between 50 and 500 nm.

After formation of this diffusion layer excess surface glass is removed from the rest of the surfaces by etching by an acid such as hydrofluoric acid.

Next, an ARC layer (antireflective coating layer) of TiOₓ, SiOₓ, TiOₓ/SiOₓ, or, in particular, SiNₓ or Si₃N₄ is formed on the n-type diffusion layer to a thickness of between 50 and 100 nm by a process, such as, for example, plasma CVD (chemical vapor deposition).

A conventional solar cell structure with a p-type silicon base typically has a negative electrode on the front-side of the cell and a positive electrode on the back-side. The front electrode is typically applied by screen printing and drying one or more front-side conductive metal pastes (front electrode forming conductive metal pastes), in particular front-side silver pastes, on the ARC layer on the front-side of the cell. The front electrode has typically the form of a grid. It is typically screen printed in a so-called H pattern which comprises (i) thin parallel finger lines (collector lines) and (ii) two busbars intersecting the finger lines at right angle. In addition, a positive back electrode consisting of a silver or silver/aluminum back anode (anodic silver or silver/aluminum rear contact) and an aluminum back anode is formed on the back-side of the cell. To this end, a back-side silver or silver/aluminum paste and an aluminum paste are applied, in particular screen printed, and successively dried on the back-side of the silicon substrate. Normally, the back-side silver or silver/aluminum paste is applied onto the silicon wafer's back-side first to form a silver or silver/aluminum back anode typically in the form of two parallel busbars or in the form of rectangles (tabs) ready for soldering interconnection strings (presoldered copper ribbons). The aluminum paste is then applied in the bare areas left uncovered by the back-side silver or silver/aluminum paste. Application of the aluminum paste is carried out with a slight overlap over the back-side silver or silver/aluminum. Firing is then typically carried out in a belt furnace for a period of 1 to 5 minutes with the wafer reaching a peak temperature in the range of 700 to 900° C. The front and back electrodes can be fired sequentially or cofired.

The aluminum paste is generally screen printed and dried on the back-side of the silicon wafer. The wafer is fired at a temperature above the melting point of aluminum to form an aluminum-silicon melt; subsequently, during the cooling phase, an epitaxially grown layer of silicon is formed that is doped with aluminum. This layer is generally called the back surface field (BSF) layer. The aluminum paste is transformed by firing from a dried state to an aluminum back anode. The back-side silver or silver/aluminum paste is fired at the same time, becoming a silver or silver/aluminum back anode. During firing, the boundary between the back-side aluminum and the back-side silver or silver/aluminum assumes an alloy state, and is connected electrically as well. The aluminum anode accounts for most areas of the back electrode, owing in part to the need to form a p+ layer. The silver or silver/aluminum back electrode is formed over portions of the back-side (often as 2 to 6 mm wide busbars) as an anode for interconnecting solar cells by means of pre-soldered copper ribbon or the like. In addition, the front-side conductive metal paste applied as front cathode sinters and penetrates through the ARC layer during firing, and is thereby able to electrically contact the n-type layer. This type of process is generally called “firing through”.

As already mentioned, the back-side silver or silver/aluminum paste is normally applied onto the silicon wafer's back-side before application of the back-side aluminum paste. It is possible to change this sequence and to apply the back-side silver or silver/aluminum paste after application of the back-side aluminum paste, whereby the back-side aluminum paste may be applied either full plane (covering the entire back surface of the silicon wafer) or only in such areas of the back surface of the silicon wafer that are not to be covered by the back-side silver paste. However, the fired adhesion (adhesion after firing) between the first applied back-side aluminum and the successively applied back-side silver or silver/aluminum is generally poor. Good fired adhesion, however, means a prolonged durability or service life of the silicon solar cell.

US 2006/0289055 A1 discloses among others a silver paste containing a glass frit comprising Sb₂O₅ as glass frit constituent. The silver paste may be applied on the silicon back surface of a silicon solar cell first to form silver rear contacts and then an aluminum paste is applied to form an aluminum back electrode.

US 2006/0001009 A1 discloses a conductive metal paste comprising antimony, antimony oxide or an antimony-containing compound that can form an antimony oxide upon firing. The conductive metal paste is used for forming a windshield defogger element.

### SUMMARY OF THE INVENTION

It has been found that the fired adhesion between the aluminum back anode and the silver back anode of a silicon solar cell can be improved when the aluminum back electrode is first applied from an aluminum paste and the silver back electrode is successively applied from a silver paste comprising glass frit which contains at least one antimony oxide.

The present invention relates to a process for the formation of a silver back anode of a silicon solar cell comprising the steps:
(1) providing a p-type silicon wafer having an aluminum back-side metallization,
(2) applying and drying a silver paste in a silver back anode pattern on the back-side of the silicon wafer, and
(3) firing the applied and dried silver paste,
   wherein the silver paste comprises particulate silver, an organic vehicle and glass frit, wherein the glass frit comprises at least one antimony oxide.

In the description and the claims the term “silver paste” is used. It shall mean a thick film conductive silver composition comprising particulate silver either as the only or as the predominant electrically conductive particulate metal.

In the description and the claims the term “silver back anode pattern” is used. It shall mean the arrangement of a silver back anode on the back-side of a solar cell silicon wafer. This arrangement is characterized by coverage of only part of the wafer's back area; typically, the silver back anode covers only a small percentage of, for example, 2 to 5 area-% of the wafer's back area. The silver back anode may be arranged, for example, in the form of several, typically two, parallel narrow, for example, 2 to 6 mm wide busbars or as rectangles or tabs ready for soldering strings for interconnecting solar cells.

### DETAILED DESCRIPTION OF THE INVENTION

In step (1) of the process of the present invention a p-type silicon wafer having an aluminum back-side metallization is provided. The silicon wafer is a mono- or polycrystalline silicon wafer as is conventionally used for the production of silicon solar cells; it has a back-side p-type region, a front-side n-type region and a p-n junction. The silicon wafer has an ARC layer on its front-side, for example, of TiOₓ, SiOₓ, TiOₓ/SiOₓ, SiNₓ or, in particular, a dielectric stack of SiNₓ/SiOₓ. Such silicon wafers are well known to the skilled person; for brevity reasons reference is expressly made to the section “TECHNICAL BACKGROUND OF THE INVENTION”. The silicon wafer is already provided with an aluminum back-side metallization, i.e. either in the form of an applied and dried back-side aluminum paste or even as already finished aluminum back anode made by applying, drying and firing a back-side aluminum paste; see the description above in the section “TECHNICAL BACKGROUND OF THE INVENTION”.

In a first embodiment of the process of the present invention, the aluminum back-side metallization covers only such areas of the back surface of the silicon wafer that are not to be covered with anodic silver rear contacts. In other words, in the first embodiment, some, for example, 2 to 5 area-% of the back surface of the silicon wafer are left uncovered by the aluminum back-side metallization thus enabling the application of anodic silver rear contacts from a back-side silver paste directly on the p-type silicon back surface in these bare areas.

In a second embodiment of the process of the present invention, the aluminum back-side metallization covers the entire back surface of the silicon wafer. Advantage of the second embodiment is, that the electrical efficiency of the silicon solar cell is improved by, for example, 0.2 to 0.5 absolute %, compared to the first embodiment.

In addition, the silicon wafer may already be provided with a conventional front-side metallization, i.e. either in the form of at least one applied and dried front-side conductive metal paste, in particular silver paste, or even as an already finished conductive metal front cathode made by applying, drying and firing at least one front-side conductive metal paste or, in particular silver paste; see the description above in the section “TECHNICAL BACKGROUND OF THE INVENTION”.

However, it is also possible to apply the front-side metallization after the silver back anode is finished.

The front-side pastes and the back-side aluminum paste may be individually fired or cofired or even be cofired with the back-side silver paste applied in step (2) of the process of the present invention.

In step (2) of the process of the present invention a silver paste is applied to form a silver back anode pattern on the back-side of the silicon wafer.

The silver paste comprises particulate silver. The particulate silver may be comprised of silver or a silver alloy with one or more other metals like, for example, copper. In case of silver alloys the silver content is, for example, 99.7 to below 100 wt. %. The particulate silver may be uncoated or at least partially coated with a surfactant. The surfactant may be selected from, but is not limited to, stearic acid, palmitic acid, lauric acid, oleic acid, capric acid, myristic acid and linolic acid and salts thereof, for example, ammonium, sodium or potassium salts.

The average particle size of the silver is in the range of, for example, 0.5 to 5 μm. The silver may be present in the silver paste in a proportion of 50 to 92 wt. %, or, in an embodiment, 55 to 84 wt. %, based on total silver paste composition.

In the present description and the claims the term “average particle size” is used. It shall mean the average particle size (mean particle diameter, d50) determined by means of laser scattering.

All statements made in the present description and the claims in relation to average particle sizes relate to average particle sizes of the relevant materials as are present in the silver paste composition.

It is possible to replace a small proportion of the silver by one or more other particulate metals. Particulate aluminum is a particular example to be named here. The proportion of such other particulate metal(s) is, for example, 0 to 10 wt. %, based on the total of particulate metals contained in the silver paste.

The silver paste comprises an organic vehicle. A wide variety of inert viscous materials can be used as organic vehicle. The organic vehicle may be one in which the particulate constituents (particulate metal, glass frit, further optionally present inorganic particulate constituents) are dispersible with an adequate degree of stability. The properties, in particular, the rheological properties, of the organic vehicle may be such that they lend good application properties to the silver paste, including: stable dispersion of insoluble solids, appropriate viscosity and thixotropy for application, in particular, for screen printing, appropriate wettability of the paste solids, a good drying rate, and good firing properties. The organic vehicle used in the silver paste may be a nonaqueous inert liquid. The organic vehicle may be an organic solvent or an organic solvent mixture; in an embodiment, the organic vehicle may be a solution of organic polymer(s) in organic solvent(s). Use can be made of any of various organic vehicles, which may or may not contain thickeners, stabilizers and/or other common additives. In an embodiment, the polymer used as constituent of the organic vehicle may be ethyl cellulose. Other examples of polymers which may be used alone or in combination include ethylhydroxyethyl cellulose, wood rosin, phenolic resins and poly(meth)acrylates of lower alcohols. Examples of suitable organic solvents comprise ester alcohols and terpenes such as alpha- or beta-terpineol or mixtures thereof with other solvents such as kerosene, dibutylphthalate, diethylene glycol butyl ether, diethylene glycol butyl ether acetate, hexylene glycol and high boiling alcohols. In addition, volatile organic solvents for promoting rapid hardening after application of the silver paste in step (2) can be included in the organic vehicle. Various combinations of these and other solvents may be formulated to obtain the viscosity and volatility requirements desired.

The organic vehicle content in the silver paste may be dependent on the method of applying the paste and the kind of organic vehicle used, and it can vary. In an embodiment, it may be from 7 to 45 wt. %, or, in another embodiment, from 10 to 45 wt. %, or, in still another embodiment, it may be in the range of 12 to 35 wt. %, in each case based on total silver paste composition. The numbers of 7 to 45 wt. %, 10 to 45 wt. % or 12 to 35 wt. % include organic solvent(s), possible organic polymer(s) and possible organic additive(s).

The organic solvent content in the silver paste may be in the range of 5 to 25 wt. %, or, in an embodiment, 10 to 20 wt. %, based on total silver paste composition.

The organic polymer(s) may be present in the organic vehicle in a proportion in the range of 0 to 20 wt. %, or, in an embodiment, 5 to 10 wt. %, based on total silver paste composition.

The silver paste comprises glass frit, i.e. one or more glass frits, as inorganic binder.

The average particle size of the glass frit(s) is in the range of, for example, 0.5 to 4 μm. The total glass frit content in the silver paste is, for example, 0.25 to 8 wt. %, or, in an embodiment, 0.8 to 3.5 wt. %.

The glass frit contains at least one antimony oxide as a glass frit constituent. Examples of suitable antimony oxides include Sb₂O₃ and Sb₂O₅, wherein Sb₂O₃ is the preferred antimony oxide.

The glass frit contains the at least one antimony oxide in a proportion corresponding to an antimony content (calculated as antimony) of, for example, 0.25 to 10 wt. %, based on total glass frit content of the silver paste composition.

The antimony content (calculated as antimony) of the silver paste as provided by the at least one antimony oxide forming the glass frit constituent lies in the range of, for example, 0.0006 to 0.8 wt. %, based on total silver paste composition. In an embodiment, said antimony content of 0.0006 to 0.8 wt. %, based on total silver paste composition, corresponds to an antimony content of 0.0008 to 1.45 wt. %, based on the total of particulate metal in the silver paste.

The preparation of the glass frits is well known and consists, for example, in melting together the at least one antimony oxide and the other constituents of the glass (other oxides in particular), and pouring such molten composition into water to form the frit. As is well known in the art, heating may be conducted to a peak temperature in the range of, for example, 1050 to 1250° C. and for a time such that the melt becomes entirely liquid and homogeneous, typically, 0.5 to 1.5 hours.

The glass may be milled in a ball mill with water or inert low viscosity, low boiling point organic liquid to reduce the particle size of the frit and to obtain a frit of substantially uniform size. It may then be settled in water or said organic liquid to separate fines and the supernatant fluid containing the fines may be removed. Other methods of classification may be used as well.

The silver paste may comprise one or more organic additives, for example, surfactants, thickeners, rheology modifiers and stabilizers. The organic additive(s) may be present in the silver paste in a total proportion of, for example, 0 to 10 wt. %, based on total silver paste composition.

In an embodiment and in accordance with the afore disclosure, the silver paste may be composed of 50 to 92 wt. % of the particulate silver, 0 to 5 wt. % of further inorganic constituents (0 wt. % of further inorganic constituents being preferred), 0.25 to 8 wt. % of glass frit and 7 to 45 wt. % of organic vehicle, wherein the wt. % total 100 wt. %, and wherein the glass frit contains the at least one antimony oxide in a proportion corresponding to an antimony content (calculated as antimony) of 0.25 to 10 wt. %, based on total glass frit content of the silver paste composition.

The silver paste is a viscous composition, which may be prepared by mechanically mixing the particulate silver and the glass frit(s) with the organic vehicle. In an embodiment, the manufacturing method power mixing, a dispersion technique that is equivalent to the traditional roll milling, may be used; roll milling or other mixing technique can also be used.

The silver paste can be used as such or may be diluted, for example, by the addition of additional organic solvent(s); accordingly, the weight percentage of all the other constituents of the silver paste may be decreased.

As already mentioned, the silver paste is applied in a silver back anode pattern on the back-side of the silicon wafer.

In the first embodiment of the process of the present invention, the silver paste is applied directly on the p-type silicon surface into the bare areas left uncovered by the aluminum back-side metallization. The silver paste is applied with a slight overlap with the aluminum back-side metallization. This slight overlap allows for making electrical connection between the aluminum back electrode and the silver back electrode by forming an alloy at the boundary between the aluminum and the silver upon firing. The inclusion of the at least one antimony oxide in the glass frit contained in the silver paste results in an improved fired adhesion between the aluminum back anode and the silver back anode in the overlapping zone.

In the second embodiment of the process of the present invention, the silver paste is applied on the aluminum back-side metallization covering the entire back surface of the silicon wafer. The inclusion of the at least one antimony oxide in the glass frit contained in the silver paste results in an improved fired adhesion between the aluminum back anode and the silver back anode.

The silver paste is applied to a dry film thickness of, for example, 5 to 30 μm. The method of silver paste application may be printing, for example, silicone pad printing or, in an embodiment, screen printing. The application viscosity of the silver paste may be 20 to 200 Pa·s when it is measured at a spindle speed of 10 rpm and 25° C. by a utility cup using a Brookfield HBT viscometer and #14 spindle.

After application, the silver paste is dried, for example, for a period of 1 to 100 minutes with the silicon wafer reaching a peak temperature in the range of 100 to 300° C. Drying can be carried out making use of, for example, belt, rotary or stationary driers, in particular, IR (infrared) belt driers.

In step (3) of the process of the present invention the dried silver paste is fired to form a silver back anode. The firing of step (3) may be performed, for example, for a period of 1 to 5 minutes with the silicon wafer reaching a peak temperature in the range of 700 to 900° C. The firing can be carried out making use of, for example, single or multi-zone belt furnaces, in particular, multi-zone IR belt furnaces. The firing may happen in an inert gas atmosphere or in the presence of oxygen, for example, in the presence of air. During firing the organic substance including non-volatile organic material and the organic portion not evaporated during the drying may be removed, i.e. burned and/or carbonized, in particular, burned. The organic substance removed during firing includes organic solvent(s), optionally present organic polymer(s) and optionally present organic additive(s). There is a further process taking place during firing, namely sintering of the glass frit with the particulate silver.

Firing may be performed as so-called cofiring together with the aluminum back-side metallization (the back-side aluminum paste) and/or front-side conductive metal paste(s) applied to the solar cell silicon wafer.

What is claimed is:

1. A process for the formation of a silver back anode of a silicon solar cell comprising the steps:
(1) providing a p-type silicon wafer having an aluminum back-side metallization,
(2) applying and drying a silver paste in a silver back anode pattern on the back-side of the silicon wafer, and
(3) firing the applied and dried silver paste,
wherein the silver paste comprises particulate silver, an organic vehicle and glass frit, wherein the glass frit comprises at least one antimony oxide.

2. The process of claim 1, wherein the silver paste contains 50 to 92 wt. % of particulate silver, based on total silver paste composition.

3. The process of claim 1, wherein the silver paste contains 7 to 45 wt. % of organic vehicle, based on total silver paste composition.

4. The process of claim 1, wherein the total glass frit content in the silver paste is 0.25 to 8 wt. %.

5. The process of claim 1, wherein the at least one antimony oxide is selected from the group consisting of Sb₂O₃ and Sb₂O₅.

6. The process of claim 1, wherein the glass frit contains the at least one antimony oxide in a proportion corresponding to an antimony content (calculated as antimony) of 0.25 to 10 wt. %, based on total glass frit content of the silver paste composition.

7. The process of claim 1, wherein the silver paste is composed of 50 to 92 wt. % of the particulate silver, 0 to 5 wt. % of further inorganic constituents, 0.25 to 8 wt. % of the glass frit and 7 to 45 wt. % of the organic vehicle, wherein the wt. % total 100 wt. %, and wherein the glass frit contains the at least one antimony oxide in a proportion corresponding to an antimony content (calculated as antimony) of 0.25 to 10 wt. %, based on total glass frit content of the silver paste composition.

8. The process of claim 1, wherein the aluminum back-side metallization covers only such areas of the back surface of the silicon wafer that are not to be covered with anodic silver rear contacts and wherein the silver paste is applied directly on the p-type silicon surface into the bare areas left uncovered by the aluminum back-side metallization and with a slight overlap with the aluminum back-side metallization.

9. The process of claim 1, wherein the aluminum back-side metallization covers the entire back surface of the silicon wafer and the silver paste is applied on the aluminum back-side metallization covering the entire back surface of the silicon wafer.

10. The process of claim 1, wherein the silver paste is applied by printing.

11. The process of claim 1, wherein the firing of the silver paste is performed as cofiring together with the aluminum back-side metallization and/or front-side conductive metal paste(s) applied to the solar cell silicon wafer.

12. A silver back anode of a silicon solar cell produced according to the process of claim 1.

13. A silicon solar cell comprising a p-type silicon wafer having a silver back anode of claim 12.
